(19) United States
(12) Patent Application Publication
(10) Pub. No.: US 2007/0128878 A1
(43) Pub. Date: Jun. 7, 2007

(54) Substrate processing apparatus and method for producing a semiconductor device

(76) Inventors: Manabu Izumi, Tokyo (JP); Yuki Ohura, Tokyo (JP)

Correspondence Address: ARMSTRONG, KRATZ, QUINTOS, HANSON & BROOKS, LLP, 1725 K STREET, NW, SUITE 1000, WASHINGTON, DC, 20006, US

(21) Appl. No.: 10/547,692

(22) PCT Filed: Feb. 27, 2004
(86) PCT No.: PCT/JP04/02334

§ 371 Date: Jul. 21, 2006

(30) Foreign Application Priority Data
Mar. 3, 2003 (JP) 2003-056260

(51) Int. Cl. C23C 16/00; H01L 21/31

(52) U.S. Cl. 438/758; 118/715

(57) ABSTRACT

A pyrogenic oxidation device (10) is comprised of a process gas supply line (38) connecting an external combustion device (39) and a supply pipe (37) connected to a processing chamber (13) and, a dilute gas supply line (45) connected to the process gas supply line (38) for supplying nitrogen gas (62), a purge gas supply line (47) for supplying nitrogen gas (62) and connecting to the exhaust pipe (37) side of the section connecting with the dilute gas supply line (45) in the process gas supply line (38), and a vent line (49) for exhausting gas and connecting to the dilute gas supply line (45) side of the section connecting with the purge gas supply line (47) in the process gas supply line (38), and stop valves (46), (48), (50) in each line opened and closed by a controller (60). A deterioration in film thickness uniformity due to residual matter can be prevented, since residual matter in the process gas supply line is prevented from flowing into the processing chamber during the purge step.

### TECHNICAL FIELD

The present invention relates to a substrate processing apparatus and a manufacturing method for semiconductor devices, and relates in particular to technology for purging the processing chamber with a purge gas, for example effective in oxide film forming apparatus for forming oxide film on semiconductor wafers (hereafter called wafers) on which semiconductor integrated circuits including semiconductor devices are formed.

### BACKGROUND ART

The oxide film forming apparatus of the conventional art for forming oxide film on wafers is comprised of a process gas supply line for supplying process gas to the processing chamber, and an exhaust line for exhausting the gas from the process chamber, and also a step for forming the oxide film in the processing chamber using the process gas supply line, as well as a purge step for pressing out residual matter such as reactive generated substances or process gas remaining in the process gas supply line (for example in Japanese Patent non-examined publication No. 2002-151499). In other words, after the oxide film forming step, this oxide film forming apparatus presses residual matter out from the process gas supply line by making a purge gas flow through the process gas supply line.

However, the above oxide film forming apparatus of the conventional art was sometimes unable to completely purge residual matter in the process gas supply line in the purge step after the oxide film forming step. Residual matter that had not been purged therefore continued to flow little by little along with the purge gas into the processing chamber after the oxide film forming step, leading to fluctuations in film thickness or a drop in film thickness uniformity. Countermeasures were thereupon contrived in the oxide film forming apparatus of the conventional art for alleviating the effects of the residual matter by heating the process gas supply line or shortening the process gas supply line.

However, along with the increasing miniaturization of semiconductor integrated circuits in recent years, advances have been made in making the thin film formed on the wafer thinner and with a high degree of uniformity in the film thickness distribution. These advances are particularly outstanding in the oxide film forming process for forming the oxide film on the wafer. Due to these advances, in the oxide film forming apparatus, the countermeasures employed to reduce residual matter by heating or shortening the process gas supply line to prevent a loss of film thickness uniformity or fluctuations in film thickness are reaching their practical limits. In other words, due to recent advances in making the film thickness uniform and making the film thinner in the oxide film forming process, countermeasures employed to reduce residual matter by heating or shortening the process gas supply line are no longer capable of sufficiently reducing the effects of residual matter and therefore may lead to problems such as a loss of film thickness uniformity or fluctuations in film thickness.

The present invention therefore has the object of providing a substrate processing apparatus and a manufacturing method for semiconductor devices utilizing that apparatus, capable of sufficiently reducing the effects of residual matter.

### DISCLOSURE OF THE INVENTION

The substrate processing apparatus of the present invention is comprised of: a processing chamber for processing a substrate, a process gas source for supplying a process gas, a process gas supply line for connecting the processing chamber with the process gas source, a purge gas supply line connected to the process gas supply line for supplying purge gas, and a vent line connected to the process gas supply line on the process gas source side (upstream side of gas flow) further than a section connecting the process gas supply line with the purge gas supply line for exhausting gas to bypass the processing chamber, wherein

the purge gas supplied from the purge gas supply line flows to both the processing chamber side (downstream side) and the vent line side (upstream side) in the process gas supply line.

The present invention can prevent residual matter on the further upstream side (process gas source side) than the section connecting with the purge gas supply line of the process gas supply line, from flowing into the processing chamber during the Purging. The adverse effects of residual matter can be prevented since the residual matter is completely expelled.

### BRIEF DESCRIPTION OF DRAWINGS

FIG. 1 is a frontal cross sectional view with one section omitted showing the pyrogenic oxidation apparatus of the first embodiment of the present invention;

FIG. 2 is a cross sectional view showing the vicinity of the section connecting with the purge gas supply line in the process gas supply line;

FIG. 3 is a frontal view with one section omitted showing the oxidizing step;

FIG. 4 is a frontal view with one section omitted showing the purging step;

FIGS. 5A and 5B are line graphs showing the effect on preventing deterioration in film thickness uniformity; FIG. 5A shows an example of the conventional art; FIG. 5B shows an example of this embodiment;

FIG. 6 is a bar graph showing the effect on preventing deterioration in film thickness uniformity; the (a) group shows the case with an example of the conventional art, the (b) group shows the case of this embodiment;

FIG. 7 is a cross sectional view showing the vicinity of the section connecting with the purge gas supply line in the process gas supply line of the second embodiment of the present invention;

FIG. 8 is a cross sectional view showing the vicinity of the section connecting with the purge gas supply line in the process gas supply line of the third embodiment of the present invention;

FIG. 9 is a cross sectional view showing the vicinity of the section connecting with the purge gas supply line in the process gas supply line of the fourth embodiment of the present invention;

FIG. 10 is a cross sectional view showing the vicinity of the section connecting with the purge gas supply line in the process gas supply line of the fifth embodiment of the present invention;

FIG. 11 is a cross sectional view showing the vicinity of the section connecting with the purge gas supply line in the process gas supply line of the sixth embodiment of the present invention.

### BEST MODE FOR CARRYING OUT THE INVENTION

The first embodiment of the present invention is described next while referring to the drawings.

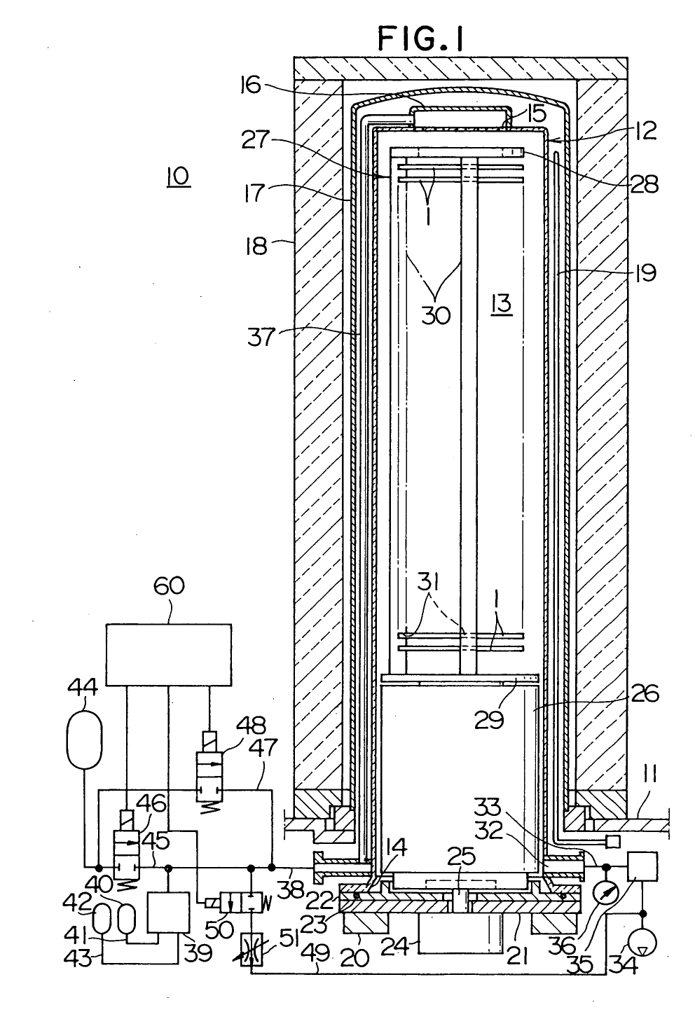

In this embodiment, the substrate processing apparatus of the present invention is functionally comprised of a pyrogenic oxidation apparatus which is one example of an oxide film forming apparatus for forming oxide film on wafers; and is structurally comprised of a batch type vertical hot wall heat treating apparatus. In other words, a substrate processing apparatus (hereafter called a “pyrogenic oxidation apparatus”) 10 of this embodiment as shown in FIG. 1, is structurally formed as a batch type vertical hot wall heat treating apparatus.

The pyrogenic oxidation apparatus 10 includes a process tube 12. The process tube 12 is formed in an integrated tubular shape utilizing quartz (SiO₂) with the top end sealed and the bottom end open. The process tube 12 is supported by a case 11 installed vertically with the center line vertical. A processing chamber 13 is formed in the tubular hollow section of the process tube 12 so that a boat 27 holding multiple wafers 1 arranged concentrically can be loaded into the processing chamber 13. The lower end opening of the process tube 12 forms a furnace opening 14 for the loading and unloading of the boat 27. Multiple flow holes 15 are formed in the thickness direction on the sealed wall (hereafter called “ceiling wall”) of the top end of the process tube 12 to disperse gas to the entire processing chamber 13. A gas retainer 16 is formed on the ceiling wall of the process tube 12 to cover the flow holes 15.

A heat equalizing tube 17 is installed concentrically on the outer side of the process tube 12. The heat equalizing tube 17 made of silicon carbide (SiC) is integrated into a tubular shape with the upper end sealed and the lower end open. The heat equalizing tube 17 is also supported by the case 11. A heater unit 18 on the outer side of the heat equalizing tube 17 is installed concentrically so as to enclose the heat equalizing tube 17. The heater unit 18 is also supported by the case 11. A thermocouple 19 is installed facing up and down between the process tube 12 and the heat equalizing tube 17. The heater unit 18 is contrived to heat uniformly or to a specified temperature distribution across the entire interior of the processing chamber 13 under the control of the controller (not shown in drawing) based on the temperature detected by the thermocouple 19.

A seal cap 21 is installed concentrically directly below the process tube 12. The seal cap 21 is formed in a disk shape approximately equivalent to the outer diameter of the process tube 12. The seal cap 21 is structured to rise and lower vertically by means of a boat elevator (only a portion is shown in the drawing) 20 contrived from a feedscrew, etc. A base 22 formed from quartz in a disk shape is installed on the seal cap 21 and is approximately equivalent to the outer diameter of the seal cap 21. In a state where the seal cap 21 is raised by the boat elevator 20, the base 22 contacts the lower end surface of the process tube 12 by way of the seal ring 23 to seal the processing chamber 13 air-tight. An electric motor 24 is installed facing upwards on the lower surface of the seal cap 21. The boat 27 is supported perpendicularly by way of a heat blocking cap 26 on a rotating shaft 25 of the electric motor 24.

The boat 27 is made up of a pair of end plates 28, 29 above and below, and multiple (three members in this embodiment) support members 30 installed perpendicularly between both end plates 28, 29. Multiple lined support grooves 31 are provided longitudinally at equidistant spaces with an opening in the same flat surface in each support member 30. Incidentally, the outer circumferential section of the wafer 1 is inserted simultaneously into the three support grooves 31. The multiple wafers 1 are held in an array on the boat 27 in a mutually centered horizontal state. The heat blocking cap 26 is installed beneath the lower side end plate 29 of the boat 27, and installed on the base 22.

An exhaust pipe 32 on the lower section of the side wall of the process tube 12 connects to the processing chamber 13, and one end of an exhaust line 33 connects to the exhaust pipe 32. An exhaust device 34 made up of a vacuum pump or blower is connected to the other end of the exhaust line 33. A pressure regulator 35 is installed along the exhaust line 33. The pressure regulator 35 is contrived to control the pressure in the processing chamber 13 to a specified pressure under the control of the controller (not shown in drawing) based on detection results from a pressure sensor 36 connected along the exhaust line 33.

A supply pipe 37 is installed on the outer side of the process tube 12. The supply pipe 37 extends upward and downward along one section of the process tube 12, and the top end of the supply pipe 37 connects to the gas retainer 16. A process gas supply line 38 connects to the bottom end of the supply pipe 37. An external combustion device 39 functioning as the process gas supply device connects to the process gas supply line 38. A detailed drawing is omitted, however, the external combustion device 39 has a combustion chamber connected to the process gas supply line 38. An oxygen gas supply line 41 connected to an oxygen (O₂) gas source 40 and a hydrogen gas supply line 43 connected to a hydrogen (H₂) gas source 42 are respectively connected to the side opposite to the process gas supply line 38 of the combustion chamber.

One end of a dilute gas supply line 45 for supplying inert gas for diluting the process gas, connects to the process gas supply line 38 on the side further downstream than the external combustion device 39. The other end of the dilute gas supply line 45 connects to a nitrogen gas supply source 44 for supplying nitrogen gas as the inert gas. A first stop valve 46 is installed along the dilute gas supply line 45. The first stop valve 46 is made up of a 2-port, 2-position, normally-closed spring-offset, solenoid-switching valve. The solenoid of the first stop valve 46 connects to a controller 60 and is controlled to open and close by the controller 60. The upstream end of a purge gas supply line 47 for supplying inert gas for purging the processing chamber 13 connects to the upstream side of the first stop valve 46 on the dilute gas supply line 45. The downstream end of the purge gas supply line 47 connects farther to the downstream side than the section connecting with the external combustion device 39 in the process gas supply line 38. A second stop valve 48 is installed along the purge gas supply line 47. This second stop valve 48 is made up of a 2-port, 2-position, normally-closed spring-offset, solenoid-switching valve. The solenoid of the second stop valve 48 connects to the controller 60 and is controlled to open and close by the controller 60.

The upstream end of a vent line 49 for exhausting gas made to bypass the processing chamber 13, connects between the section connecting with the external combustion device 39 and the section connecting with the purge gas supply line 47 in the process gas supply line 38. The downstream end of the vent line 49 connects to the exhaust line 33. A third stop valve 50 is installed along the vent line 49. This third stop valve 50 is made up of a 2-port, 2-position, normally-closed spring-offset, solenoid-switching valve. The solenoid of the third stop valve 50 connects to the controller 60 and is controlled to open and close by the controller 60. A flow control device 51 comprised of a MFC (mass flow controller), etc. is installed on the downstream side of the third stop valve 50 in the vent line 49. The flow control device 51 is contrived to regulate by way of the controller 60, the flow rate of the gas flowing on the vent line 49. A flow meter may be installed instead of the flow control device 51.

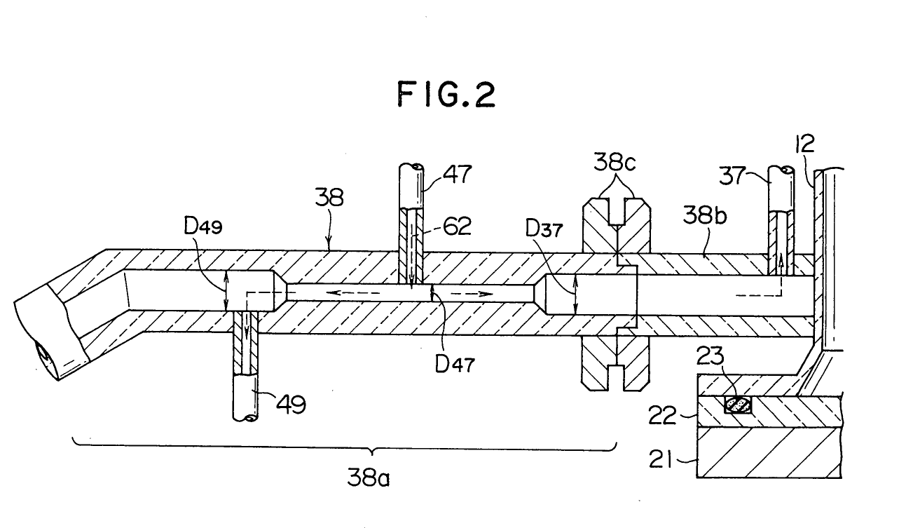

As shown in FIG. 2, the inner diameter D₄₇ of the section where the purge gas supply line 47 connects in the process gas supply line 38 is set smaller than the inner diameter D₄₉ of the section connecting to the vent line 49 and the inner diameter D₃₇ of the section connecting to the supply pipe 37. The inner diameter D₄₇ of the purge gas line connecting section should be equivalent to the inner diameter of the outer diameter ¼ to ⅜ inch pipe or in other words is preferably 4.35 to 7.52 millimeters. The inner diameter of the vent line 49 and the inner diameter D₄₉ of the vent line connecting section and the inner diameter D₃₇ of the supply pipe connecting section also should be at least an inner diameter for a pipe with ¼ to ⅜ inch outer diameter or in other words, should preferably set from approximately 4.35 to 7.52 millimeters or more.

Here, the inner diameter D₄₇ of the section where the purge gas supply line 47 connects in the process gas supply line 38 is preferably set to “½” or less than the inner diameter D₄₉ of the section connecting to the vent line 49 or the inner diameter D₃₇ of the section connecting to the supply pipe 37. In other words, the inner diameter is preferably set so that “D₄₇≦D₃₇/2” or “D₄₇≦D₄₉/2”. For example, when the inner diameter D₄₉ of the section connecting to the vent line 49 and the inner diameter D₃₇ of the section connecting to the supply pipe 37 were set from 10 to 12 millimeters, then the inner diameter D₄₇ of the section connecting to the purge gas supply line 47 in the process gas supply line 38 is preferably set from 5 to 6 millimeters.

In the present embodiment, the inner diameter D₄₉ of the section connecting to the vent line 49 and the inner diameter D₃₇ of the section connecting to the supply pipe 37 are set the same inner diameter as the process gas supply line 38 of the conventional art, and the inner diameter D₄₇ of the section connecting to the purge gas supply line 47 are set to less than “½” of the inner diameter of the process gas supply line 38 of the conventional art. However, the inner diameter D₄₇ of the section connecting to the purge gas supply line 47 may be set to an inner diameter equivalent to the inner diameter of the process gas supply line 38 of the conventional art, and the inner diameter D₄₉ of the section connecting to the vent line 49 and the inner diameter D₃₇ of the section connecting to the supply pipe 37 may be set to double or more the inner diameter of the process gas supply line 38 of the conventional art.

As shown in FIG. 2, a section of the process gas supply line 38 is made up of a conductance pipe 38a. The conductance pipe 38a is connected to allow attachment or removal by means of a flange pipe joint 38c on a root 38b on the process tube 12 side of the process gas supply line 38. The conductance pipe 38a is made of quartz to prevent impurities and also maintain corrosion resistance.

The purge gas supply line 47 and the vent line 49 are connected to the conductance pipe 38a as previously described. The reason for the making the inner diameter of the conductance pipe 38a different is to form a pressure differential in the interior of the conductance pipe 38a. The reason for setting the inner diameter D₄₇ of the section connecting to the purge gas supply line 47 smaller (narrower) than the inner diameter D₄₉ of the section connecting to the vent line 49 and the inner diameter D₃₇ of the section connecting to the supply pipe 37, is to raise the pressure in that section (narrow section) to a pressure higher than that in the fat pipe sections on both sides. The reason for setting the inner diameter D₄₉ of the section connecting to the vent line 49 and the inner diameter D₃₇ of the section connecting to the supply pipe 37 larger (fatter) than the inner diameter D₄₇ of the section connecting to the purge gas supply line 47 is to make the pressure of those fat sections lower than the pressure in the narrow section. Doing the above makes the gas from the purge gas supply line 47 flow easily to the vent line 49 side and the supply pipe 37 side.

The method for processing the wafer as one process of the semiconductor device manufacturing process (method) is described next, taking the forming of a wafer oxide film using the pyrogenic oxidation apparatus of the above structure as an example.

In the case of the oxide film forming device as shown in FIG. 1, the boat 27 holding an array of multiple wafers 1, is loaded onto the base 22 on the seal cap 21 in a state where the arrayed direction of the wafer 1 group is vertical. The boat 27 raised by the boat elevator 20 is loaded into the processing chamber 13 from the furnace opening 14 of the process tube 12, and placed in the processing chamber 13 while still held by the seal cap 21. In this state, the base 22 is sealed by the seal ring 23 to seal the processing chamber 13 air-tight.

In a state where the processing chamber 13 is sealed airtight by the seal ring 23, the interior of the processing chamber 13 is exhausted by the exhaust line 33, and heated to a specified temperature by the heater unit 18. When the wafer temperature reaches the processing temperature and stabilizes, the oxygen gas and the hydrogen gas are respectively supplied at specified flow quantities by the oxygen gas supply line 41 and the hydrogen gas supply line 43 to the combustion chamber of the external combustion device 39. When the temperature of the combustion chamber of the external combustion device 39 is heated to the combustion temperature of the hydrogen gas or higher, water vapor (H₂O) as a process gas 61, is generated due to the combustion reaction of the oxygen gas and hydrogen gas.

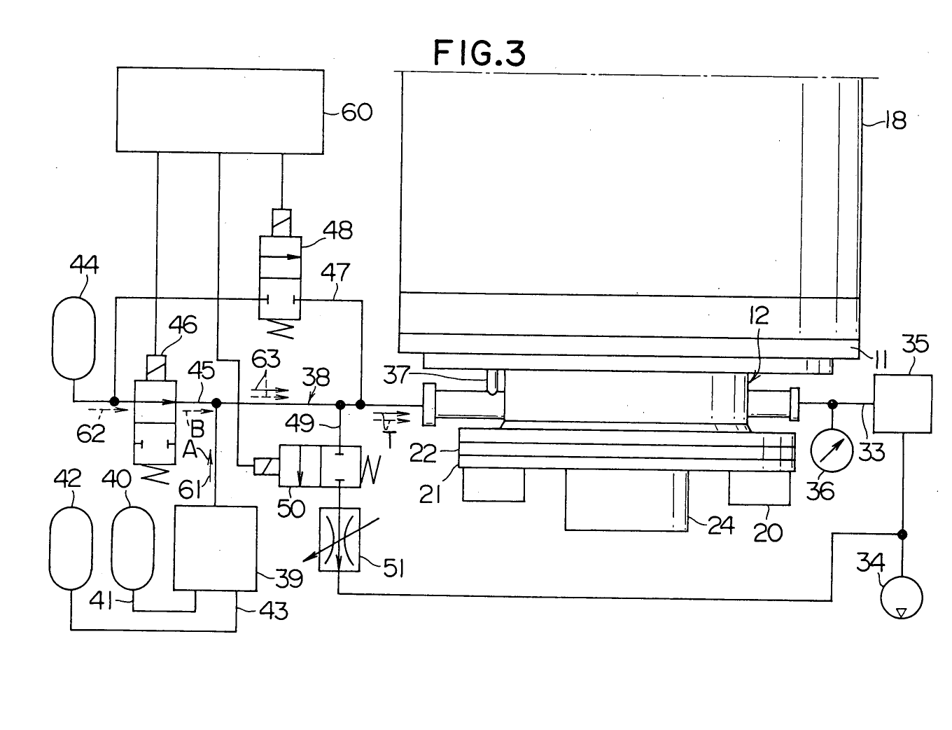

Next, as shown in FIG. 3, the controller 60 closes the second stop valve 48 of the purge gas supply line 47 and the third stop valve 50 of the vent line 49 along with opening the first stop valve 46 of the dilute gas supply line 45. In the processing chamber 13, a mixed gas 63 made up of the process gas 61 and a nitrogen gas 62 as the inert gas functioning as the dilute gas is in this way supplied from the process gas supply line 38 to the supply pipe 37, and supplied by way of the supply pipe 37 to the gas retainer 16 of the process tube 12. The mixed gas 63 supplied to the gas retainer 16 is uniformly dispersed across the entire interior of the processing chamber 13 by the flow holes 15. The mixed gas 63 dispersed uniformly in the processing chamber 13 flows down the processing chamber 13 while uniformly contacting each of the multiple wafers 1 held in the boat 27. The mixed gas 63 is exhausted to outside the processing chamber 13 from the exhaust pipe 32 by the exhaust force of the exhaust line 33. An oxide film is formed on the surface of the wafer 1 by the oxidizing reaction of the process gas 61 due to contact with the mixed gas 63 on the surface of the wafer 1.

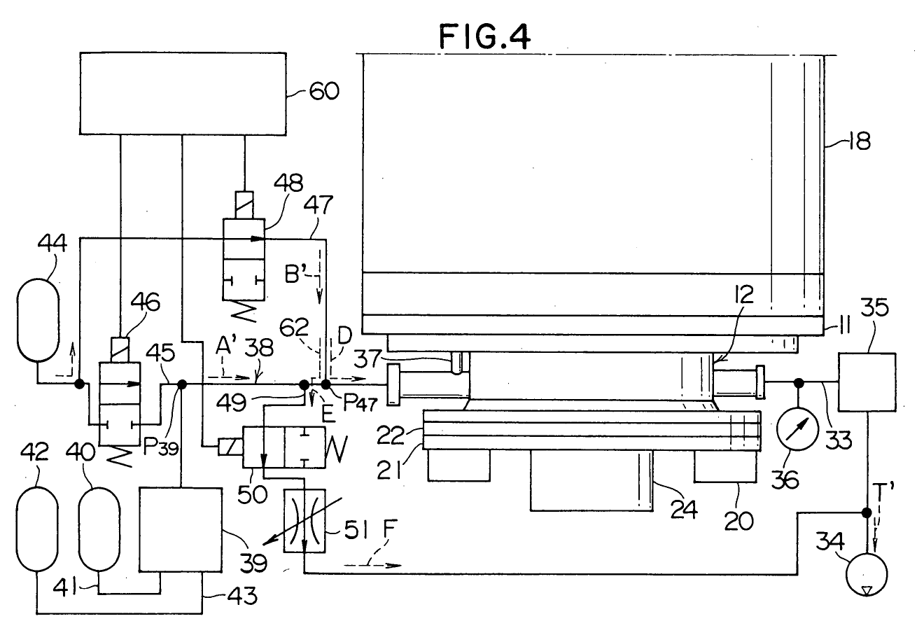

As shown in FIG. 4, when the pre-established processing time has elapsed, the controller 60 stops the supply of the oxygen gas and the hydrogen gas to the combustion chamber of the external combustion device 39. Next, along with closing the first stop valve 46 of the dilute gas supply line 45, the controller 60 also respectively opens the second stop valve 48 of the purge gas supply line 47 and the third stop valve 50 of the vent line 49. The controller 60 at this time, controls the flow to allow a small flow rate of the nitrogen gas 62 from the first stop valve 46 of the dilute gas supply line 45.

As shown in FIG. 4, the nitrogen gas (hereafter may be called purge gas) 62 branching from the purge gas supply line 47 to the vent line 49 side, flows backwards in the process gas supply line 38, and then flows from the process gas supply line 38 to the vent line 49 to the exhaust line 33. The residual matter such as reactive substances and process gas remaining on the external combustion device 39 side of the section connecting with the purge gas supply line 47 in the process gas supply line 38 and dispersing to the processing chamber 13 side, are in this way forced to flow by way of the vent line 49 to the exhaust line 33. In other words, the residual matter dispersing towards the processing chamber 13 from the process gas supply line 38 on the external combustion chamber 39 side of the section connecting to the purge gas supply line 47, makes a complete detour around the processing chamber 13 by way of the vent line 49 and is evacuated via the exhaust line 33 so that none of the residual matter flows into the processing chamber 13. The ratio of the exhaust flow rate of the purge gas 62 to the supply pipe 37 side to the exhaust flow rate on the vent line 49 can be adjusted by controlling the flow rate on the vent line 49 by the flow control device 51 installed on the vent line 49.

In the oxidizing step as shown in FIG. 3, if the total gas flow rate supplied from each gas supply line or in other words, the gas flow rate supplied to the processing chamber 13 is set as T, the gas flow rate from the external combustion chamber 39 is set as A, and the flow rate of the purge gas 62 from the dilute gas supply line 45 is set as B, then the T=A+B is obtained.

In the purge step shown in FIG. 4, if the total gas flow rate supplied from each gas supply line is set as T′, the flow rate of the purge gas from the purge gas supply line 47 is B′, the flow rate of the purge gas supplied to the processing chamber 13 is D, the flow rate exhausted by way of the vent line 49 is E, the flow rate of the inert gas of the small flow rate from the dilute gas supply line 45 is A′, and the total gas flow rate exhausted by way of the vent line 49 is set as F, then E+D=B′, E+A′=F, D+F=T′ is obtained.

During this purge step, the flow rate B′ purge gas in the section connecting the purge gas supply line 47 with the process gas supply line 38 is apportioned between the flow rate D supplied to the processing chamber 13, and the flow rate E evacuated by way of the vent line 49 so that the controller 60 determines the flow rate D of the gas supplied to the processing chamber 13, and the flow control device 51 adjusts the “A′+E” flow rate so that the pressure P39 for the position on the external combustion device 39 side (gas upstream flow side of process gas) of the section connecting with the purge gas supply line 47 in the process gas supply line 38 does not rise higher than the pressure P47 of the section connecting with the purge gas supply line 47 in the process gas supply line 38.

On the other side, the purge gas 62 branching from the purge gas supply line 47 to the supply pipe 37 side, is supplied to the gas retainer 16 of the process tube 12 by flowing through the process gas supply line 38 to the supply pipe 37. By setting the inner diameter D₄₇ of the purge gas line connecting section in the process gas supply line 38 smaller than the inner diameter D₄₉ of the vent line connecting section at this time, the pressure of the purge gas supply line connecting section becomes higher than the pressure of the vent line connecting section so that the diffusion of residual matter from the external combustion section 39 side to the supply pipe 37 side in the process gas supply line 38 can be prevented. The purge gas 62 supplied to the gas retainer 16 disperse uniformly across the entire interior of the processing chamber 13 by means of the flow holes 15. The purge gas 62 uniformly dispersed in the processing chamber 13 flows down the processing chamber 13 while uniformly contacting each of the multiple wafers 1 held in the boat 27. The purge gas 62 is exhausted to outside the processing chamber 13 from the exhaust pipe 32 by the exhaust force of the exhaust line 33. Residual matter such as reactive substances and the process gas 61 that remained in the processing chamber 13 are made to flow out by the flow of this purge gas 62. The purge gas 62 further contains no residual matter from the process gas supply line 38 so that deterioration of film thickness uniformity on the wafer surface (hereafter called “film thickness uniformity”) due to residual matter contained in the purge gas 62 in the oxide film formed on the wafer 1 in the above described oxidizing process can be prevented.

After the purge step is finished, the boat unloading step is performed. In other words, the seal cap 21 is lowered by the boat elevator 20 and the boat 27 is unloaded out of the processing chamber 13. When the boat unloading step is complete, the wafer discharge step is performed for extracting the processed wafers 1 from the boat 27.

After the boat unloading step, with no boat 27 or in other words no wafers 1 in the processing chamber 13, the controller 60 opens the first stop valve 46 of the dilute gas supply line 45 to supply inert gas from the external combustion chamber 39 side so that residual matter is removed on the side further upstream (external combustion chamber 39 side) than the vent line 49 in the process gas supply line 38. The inert gas supplied from the external combustion chamber 39 side flows through the process gas supply line 38, and after passing through the processing chamber 13 is evacuated from the exhaust line 33. The purge gas supply line 47 and the vent line 49 may be used in the purge step after this unloading step. As described above, in the purge step (in a state with the boat 27 in the process chamber 13) after the oxidizing step, the residual matter farther upstream (external combustion chamber 39 side) than the vent line 49 in the process gas supply line 38 can be removed by allowing a small amount of inert gas to flow from the external combustion chamber 39 side.

Batch processing of the wafers by the pyrogenic oxidation apparatus can be performed by repeating the above described operation.

The present embodiment can prevent residual matter in the process gas supply line 38 from flowing into the processing chamber 13 in the purge step as described above so that the phenomenon in which film thickness uniformity in the oxide film formed on the wafer in the oxidizing step is deteriorated due to residual matter can be prevented beforehand.

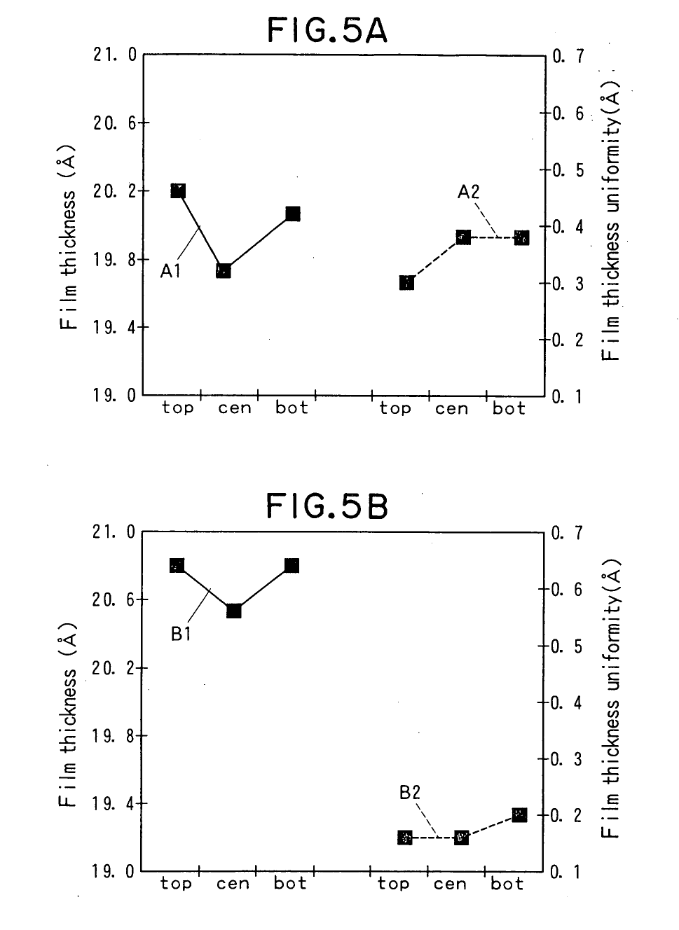

FIGS. 5A and 5B are line graphs showing the effect on preventing deterioration in film thickness uniformity. FIG. 5A shows the case of the conventional art. FIG. 5B shows the case of this embodiment.

In FIGS. 5A and 5B, the horizontal axis shows the wafer position on the boat. Here, “top” indicates the top end section, “cen” indicates the center section, and “bot” indicates the bottom end section. The vertical left axis indicates the film thickness (Å). The vertical right axis indicates the film thickness uniformity (standard deviation shown by Å).

In FIG. 5A, the film thickness is shown by the solid line A1 and the film thickness uniformity is shown by the dashed line A2. In FIG. 5B, the film thickness is shown by the solid line B1 and the film thickness uniformity is shown by the dashed line B2.

The processing conditions were the same for both the conventional art and the present embodiment and are described next.

A boat loaded with one hundred and fifty wafers was loaded into a processing chamber heated to 600° C. The processing chamber temperature was then raised to 650° C. and after the substrate temperature rose to the processing temperature and stabilized, the oxidizing step was implemented by allowing a flow of the process gas (water vapor) at 1 SLM (standard liters per minute) in an air atmosphere at 650° C. The annealing step was next performed in an atmosphere of 900° C. The process time was 30 minutes. The purge step was then implemented by flowing nitrogen gas at 20 SLM. The purging time was a 5 minute period. After this purging step, the temperature in the processing chamber was lowered to 650° C., and the boat was then unloaded from the processing chamber.

As clearly shown by comparing FIG. 5A and FIG. 5B, in the case of the present embodiment, in spite of the fact that the film thickness shown in the solid line B1 increased more than the film thickness of the conventional art shown in the solid line A1, the film thickness uniformity shown by the dashed line B2 was 0.2 Å or less. The film thickness uniformity was drastically improved compared to that (0.3 to 0.4 Å) of the conventional art shown by the dashed line A2.

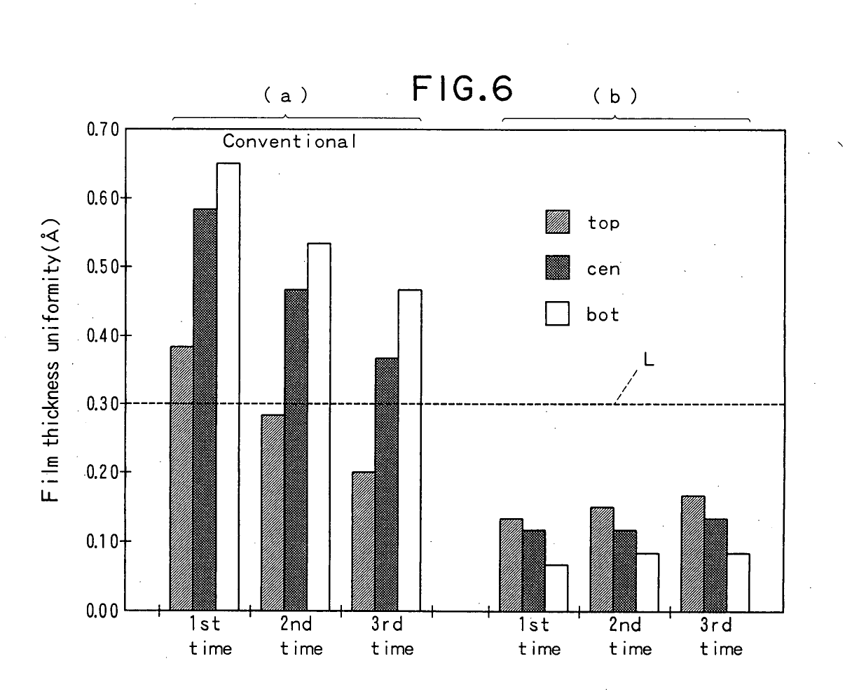

FIG. 6 is a bar graph showing the effect on preventing deterioration in film thickness uniformity. The (a) group shows the case with an example of the conventional art. The (b) group shows the case of this embodiment.

In FIG. 6, the horizontal axis shows each one sequence (oxidizing step to purge step). FIG. 6 shows when the same sequence was repeated 3 times. The “top” bar, the “cen” bar, and the “bot” bar respectively show the cases when the wafer is positioned on the top end section, the center section, and the bottom end section. The vertical axis indicates the film thickness uniformity (standard deviation shown by Å). The dashed line L shows the standard deviation (0.3 Å) of the target value.

The processing conditions were the same for both the conventional art and the present embodiment and the same as in FIG. 5.

In the (a) group of FIG. 6 showing the case of the conventional art, the film thickness uniformity improved each time the count was increased from the 1st time to the 2nd time, to the 3rd time, however, the uniformity was unstable. Moreover, the target value L could not be attained. In contrast, in the present embodiment shown in the (b) group of FIG. 6, the film thickness uniformity was almost completely stable even when the count was increased from the 1st time to the 2nd time, to the 3rd time. Moreover, the film thickness uniformity was 0.2 Å or less and was considerably less than the target value L.

The present embodiment can prevent residual matter (within the external combustion device 38 and within the process gas supply line 38) on the upstream side of the section connecting with the purge gas supply line 47 in the process gas supply line 38, from flowing (dispersing) into the processing chamber 13 during purging of the processing chamber 13 while wafers 1 are present within the processing chamber 13, by allowing purge gas to flow both upstream and downstream of the section connecting with the purge gas supply line 47 in the process gas supply line 38.

Further, by utilizing the conductance pipe 38a as a portion of the process gas supply line 38, and by connecting the purge gas supply line 47 and the vent line 49 to the pipe 38a, and by installing the pipe 38a on the root 38b of the process tube 12 side of the process gas supply line 38 by the flange joint 38c for freely detaching and attaching, the preexisting pyrogenic oxidation apparatus can be easily applied and at a low cost.

The present invention is not limited by the above described embodiments and needless to say can be changed in diverse arrangements without departing from the spirit or the scope of this invention.

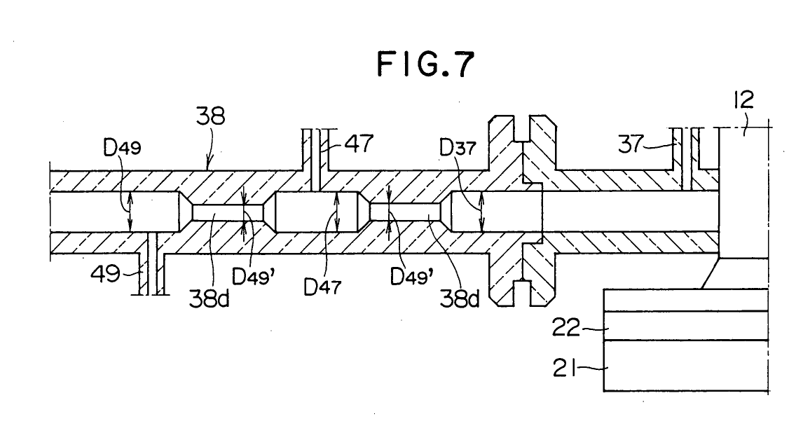

For example, the conductance pipe 38a functioning as a section of the process gas supply line 38 may be configured as shown in FIG. 7 through FIG. 11.

In the embodiment shown in FIG. 7, the inner diameter D₄₇ of the section where the purge gas supply line 47 connects in the process gas supply line 38 is set to the same size as the inner diameter D₄₉ of the section connecting with the vent line 49 and the inner diameter D₃₇ of the section connecting with the supply pipe 37. There are a pair of narrow pipe sections 38d with inner diameters D₄₉′ narrower than the inner diameter D₄₉ of the section connecting with the vent line 49. One pipe section 38d is provided between the section connecting with the purge gas supply line 47 in the process gas supply line 38 and the section connecting with the vent line 49. The other pipe section 38d is provided between the section connecting with the purge gas supply line 47 and the section connecting with the supply pipe 37.

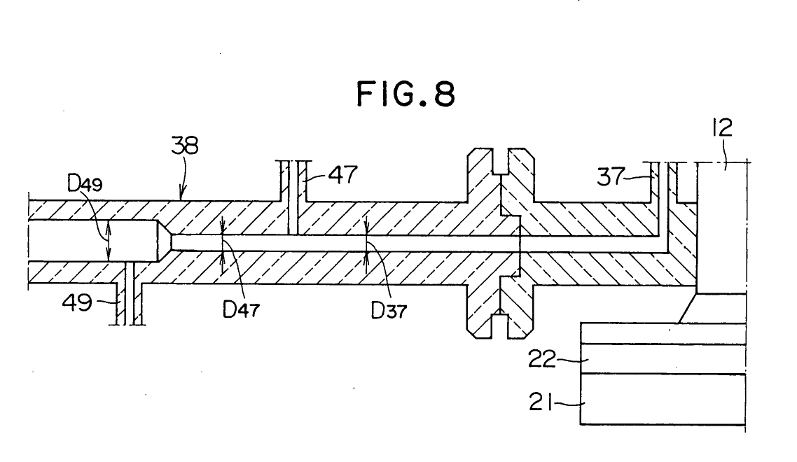

In the embodiment shown in FIG. 8, the inner diameter D₄₉ of the section connecting with the vent line 49 in the process gas supply line 38 is set larger (D₄₉>D₄₇, D₄₉>D₃₇) than the inner diameter D₄₇ of the section connecting with the purge gas supply line 47 and the inner diameter D₃₇ of the section connecting with the supply pipe 37. In the present embodiment, the same effect as in the above described embodiments can be attained by controlling the flow rate with the flow control device 51 installed on the vent line 49.

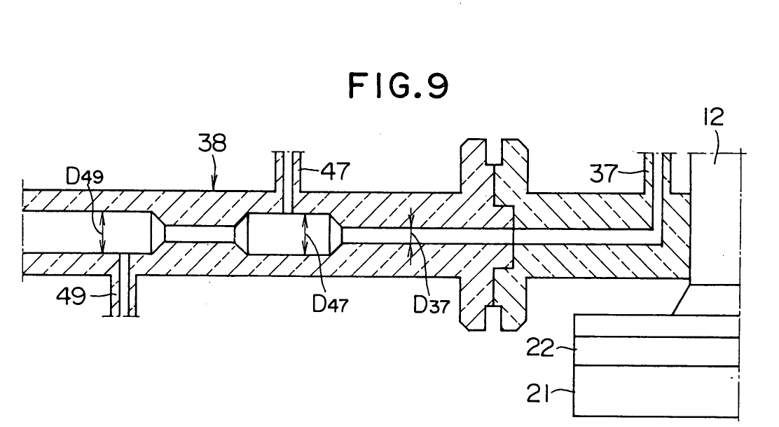

In the embodiment shown in FIG. 9, the inner diameter D₄₉ of the section connecting with the vent line 49 in the process gas supply line 38 and the inner diameter D₄₇ of the section connecting with the purge gas supply line 47 is set larger (D₄₉>D₃₇, D₄₇>D₃₇) than the inner diameter D₃₇ of the section connecting with the supply pipe 37. In the present embodiment, the same effect as in the above described embodiments can be attained by controlling the flow rate with the flow control device 51 installed on the vent line 49.

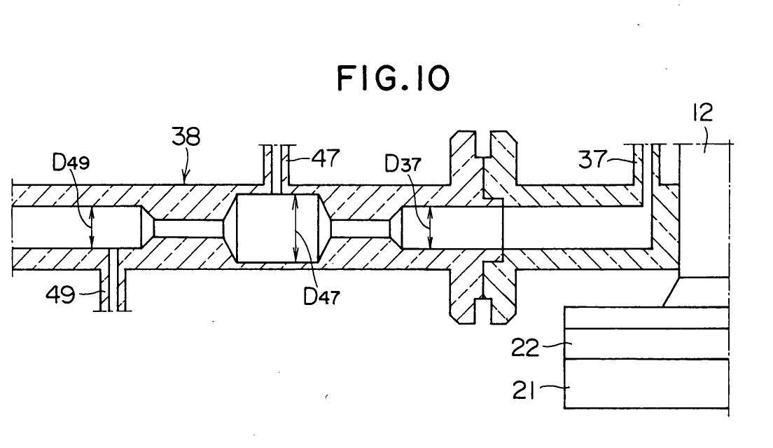

In the embodiment shown in FIG. 10, the inner diameter D₄₇ of the section connecting with the purge gas supply line 47 in the process gas supply line 38 is set larger (D₄₇>D₄₉, D₄₇>D₃₇) than the inner diameter D₄₉ of the section connecting with the vent line 49 and the inner diameter D₃₇ of the section connecting with the supply pipe 37.

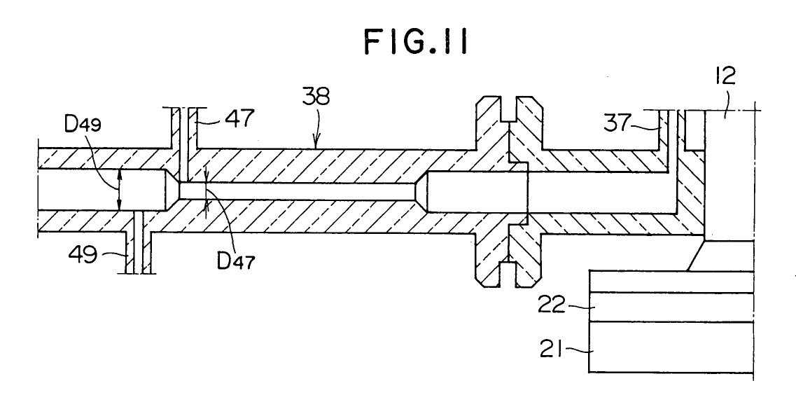

In the embodiment shown in FIG. 11, the inner diameter D₄₇ of the section connecting with the purge gas supply line 47 in the process gas supply line 38 is set smaller (D₄₇<D₄₉) than the inner diameter D₄₉ of the section connecting with the vent line 49, and the section connecting with the purge gas supply line 47 is adjacent to the section connecting with the vent line 49.

The source for supplying purge gas to the purge gas supply line may be installed separately from the source for supplying inert gas connected to the dilute gas supply line.

The dilute gas supply line may be omitted. Also, a stop valve may be installed if necessary.

The process is not limited to forming an oxide film and can be applied to general substrate processes implementing a purge step after a step utilizing a process gas such as for processes for forming a CVD film such as silicon nitrided film or polysilicon film, or diffusion processing, processes for carrier activizing after ion implantation or reflow for flatness or annealing processes, other thermal treatment processes, etc.

The invention is further not limited to pyrogenic oxidation apparatus and may be applied to general substrate processing apparatus such as other oxidation apparatus, diffusion apparatus, annealing apparatus and other thermal treatment apparatus, etc.

The invention is further not limited to substrate processing apparatus for new manufacture and may be applied by modifying preexisting substrate processing apparatus. In such cases, the structure of the preexisting apparatus can be retained and the apparatus adapted easily and at a low cost by merely providing the conductance pipe, purge gas supply line, and vent line.

The processing of wafers was described in the above embodiment, however, the substrate for processing may be a photomask or printed circuit board, liquid crystal panel, compact disk as well as magnetic disk, etc.

1. A substrate processing apparatus comprising: a processing chamber for processing a substrate, a process gas supply device for supplying a process gas, a process gas supply line for connecting the processing chamber with the process gas supply device, a purge gas supply line connected to the process gas supply line for supplying purge gas, and a vent line connected to the process gas supply line on the process gas supply device side further than a section connecting the process gas supply line with the purge gas supply line for exhausting gas to bypass the processing chamber, wherein
the purge gas supplied from the purge gas supply line flows to both the processing chamber side and the vent line side of the process gas supply line.

2. The substrate processing apparatus according to claim 1, wherein the purge gas supplied from the purge gas supply line and flowing to the processing chamber side of the process gas supply line is supplied into the processing chamber containing the substrate.

3. The substrate processing apparatus according to claim 1, wherein stop valves are respectively installed in the purge gas supply line and in the vent line, and a controller is installed, said controller controlling the stop valve for the purge gas supply line and the stop valve for the vent line to close during the substrate processing, and controlling the stop valve for the purge gas supply line and the stop valve for the vent line to open during the purging of the processing chamber.

4. The substrate processing apparatus according to claim 1, wherein a flow control device or a flow meter is installed in the vent line.

5. The substrate processing apparatus according to claim 1, wherein in the process gas supply line, at least the section connecting with the purge gas supply line and the vent line is made of quartz.

6. The substrate processing apparatus according to claim 1, wherein the process gas supply device is an external combustion device for combusting and reacting hydrogen gas and oxygen gas to generate water vapor.

7. The substrate processing apparatus according to claim 1, wherein the process gas is water vapor, and the process is a process to form oxide film on the substrate.

8. The substrate processing apparatus according to claim 1, wherein a dilute gas supply line for supplying dilute gas is installed on the process gas supply line on the process gas supply device side further than the section connecting the process gas supply line with the purge gas supply line.

9. The substrate processing apparatus according to claim 8, wherein the dilute gas supply line and the purge gas supply line are connected to one inert gas supply line on the upstream side of the process gas supply device.

10. The substrate processing apparatus according to claim 8, wherein stop valves are respectively installed in the dilute gas supply line and in the purge gas supply line, and a controller is installed, said controller controlling the stop valve for the dilute gas supply line to open and the stop valve for the purge gas supply line to close during the substrate processing, and controlling the stop valve for the dilute gas supply line to close and the stop valve for the purge gas supply line to open during the purging of the processing chamber.

11. The substrate processing apparatus according to claim 8, wherein stop valves are respectively installed in the dilute gas supply line and in the purge gas supply line and in the vent line, and a controller is installed, said controller controlling the stop valve for the dilute gas supply line to open and the stop valve for the purge gas supply line and the stop valve for the vent line to close during the substrate processing, and controlling the stop valve for the dilute gas supply line to close and the stop valve for the purge gas supply line and the stop valve for the vent line to open during the purging of the processing chamber.

12. A substrate processing apparatus comprising: a processing chamber for processing a substrate, a process gas supply device for supplying a process gas, a process gas supply line for connecting the processing chamber with the process gas supply device, a purge gas supply line connected to the process gas supply line for supplying purge gas, and a vent line connected to the process gas supply line on the process gas supply device side further than a section connecting the process gas supply line with the purge gas supply line for exhausting gas to bypass the processing chamber, wherein
the inner diameter of the section connecting with the purge gas supply line of the process gas supply line is set smaller than the inner diameter of the section connecting with the vent line of the process gas supply line.

13. The substrate processing apparatus according to claim 12, wherein the inner diameter of the section connecting with the purge gas supply line of the process gas supply line is set smaller than the inner diameter of the vent line side and the processing chamber side further than said section of the process gas supply line.

14. A substrate processing apparatus comprising: a processing chamber for processing a substrate, a process gas supply device for supplying a process gas, a process gas supply line for connecting the processing chamber with the process gas supply device, a purge gas supply line connected to the process gas supply line for supplying purge gas, and a vent line connected to the process gas supply line on the process gas supply device side further than a section connecting the process gas supply line with the purge gas supply line for exhausting gas to bypass the processing chamber, wherein
the pressure of the section connecting with the purge gas supply line of the process gas supply line is set larger than the pressure of the section connecting with the vent line of the process gas supply line.

15. The substrate processing apparatus according to claim 14, wherein the pressure of the section connecting with the purge gas supply line of the process gas supply line is made larger than the pressure of the vent line side and the pressure of the processing chamber side further than said section of the process gas supply line.

16. A substrate processing apparatus comprising: a processing chamber for processing a substrate, a process gas supply device for supplying a process gas, a process gas supply line for connecting the processing chamber with the process gas supply device, a purge gas supply line connected to the process gas supply line for supplying purge gas, and a vent line connected to the process gas supply line on the process gas supply device side further than a section connecting the process gas supply line with the purge gas supply line for exhausting gas to bypass the processing chamber, wherein
a narrow pipe section with an inner diameter smaller than the inner diameter of the section connecting with the vent line of the process gas supply line, is installed on the process gas supply line between the section connecting with the purge gas supply line of the process gas supply line, and the section connecting with the vent line of the process gas supply line.

17. The substrate processing apparatus according to claim 16, wherein a narrow pipe section with an inner diameter smaller than the inner diameter of the section connecting with the vent line of the process gas supply line, is installed on both the vent line side and the processing chamber side further than the section connecting with the purge gas supply line of the process gas supply line.

18. A method for manufacturing semiconductor devices comprising the steps of:
loading a substrate into a processing chamber,
Processing the substrate by supplying a process gas to the processing chamber by way of a process gas supply line connecting the processing chamber with a process gas supply device, along with evacuating the processing chamber by way of an exhaust line connecting to the processing chamber,
supplying purge gas to the process gas supply line by way of a purge gas supply line connecting to the process gas supply line, along with evacuating the gas through the processing chamber by way of the exhaust line, and also evacuating the gas from a vent line connected to the process gas supply line on the process gas supply device side further than a section connecting the process gas supply line with the purge gas supply line and,
unloading the substrate from the processing chamber.

19. The method for manufacturing semiconductor devices according to claim 18, wherein in the step for supplying purge gas, the purge gas is also supplied from the process gas supply device side.

20. The method for manufacturing semiconductor devices according to claim 18, comprising a step for supplying purge gas to the processing chamber from the process gas supply device side by way of the process gas supply line, along with evacuating from the exhaust line, after unloading the substrate from the substrate.

21. The method for manufacturing semiconductor devices according to claim 18, wherein the process gas is water vapor, and the process is a process to form an oxide film on the substrate.
